(19) United States
(12) Patent Application Publication
(10) Pub. No.: US 2021/0246573 A1
(43) Pub. Date: Aug. 12, 2021

(54) SILICON CARBIDE CRYSTAL GROWING APPARATUS AND CRYSTAL GROWING METHOD THEREOF

(71) Applicant: Winsheng Material Technology (WMT) Co., Ltd., New Taipei City (TW)

(72) Inventors: Yun-Fu Chen, New Taipei City (TW); Chun-Sheng Peng, New Taipei City (TW); Min-Sheng Chu, New Taipei City (TW); Wei-Tse Hsu, New Taipei City (TW)

(73) Assignee: Winsheng Material Technology (WMT) Co., Ltd., New Taipei City (TW)

(21) Appl. No.: 16/866,509

(22) Filed: May 4, 2020

Related U.S. Application Data
(60) Provisional application No. 62/975,185, filed on Feb. 11, 2020.

(51) Int. Cl. C30B 31/18; C30B 23/00; C30B 23/02; C30B 29/36; C23C 14/58; C23C 14/06; C23C 14/24; C23C 16/455; C23C 16/52

(52) U.S. Cl. CPC C30B 31/18; C30B 23/005; C30B 23/02; C30B 29/36; C23C 16/52; C23C 14/0635; C23C 14/24; C23C 16/45525; C23C 14/5846

(57) ABSTRACT

A silicon carbide crystal growing apparatus includes a physical vapor transport unit and an atomic layer deposition unit. The physical vapor transport unit has a crystal growing furnace configured to grow a silicon carbide crystal in an internal space of the crystal growing furnace. The atomic layer deposition unit is coupled to the crystal growing furnace and configured to perform an atomic doping operation on the silicon carbide crystal. A silicon carbide crystal growing method is also provided.

### CROSS-REFERENCE TO RELATED APPLICATION

This application claims the priority benefit of U.S. provisional application Ser. No. 62/975,185, filed on Feb. 11, 2020. The entirety of the above-mentioned patent application is hereby incorporated by reference herein and made a part of this specification.

### BACKGROUND

### Field of the Disclosure

The disclosure relates to a crystal growing apparatus and a crystal growing method, and particularly relates to a silicon carbide crystal growing apparatus and a crystal growing method thereof.

### Description of Related Art

It is very common to use physical vapor transport (PVT) to grow silicon carbide crystals in silicon carbide crystal growing apparatus and perform doping on silicon carbide crystals to adjust the resistivity thereof.

However, the resistivity of silicon carbide crystals will change sensitively with the doping effect. For example, if the doping effect is inappropriate, it is likely to adversely affect the resistivity and crystal yield of the silicon carbide crystal. Therefore, how to improve the doping effect to reduce the probability of adverse effects caused by doping on the resistivity and crystal yield of the silicon carbide crystal, and thus improving the reliability and quality of subsequent products has become an urgent issue to be solved.

### SUMMARY OF THE DISCLOSURE

The disclosure provides a silicon carbide crystal growing apparatus and a crystal growing method thereof, which can improve the doping effect to reduce the probability of adversely affecting the resistivity and crystal yield of the silicon carbide crystal due to excessive or uneven doping, and can reduce the impurities in the crystal to improve the purity of the crystal, such that the reliability and quality of subsequent products can be enhanced.

The silicon carbide crystal growing apparatus of the disclosure includes a physical vapor transport unit and an atomic layer deposition unit. The physical vapor transport unit has a crystal growing furnace configured to grow a silicon carbide crystal in an internal space of the crystal growing furnace. The atomic layer deposition unit is coupled to the crystal growing furnace and configured to perform an atomic doping operation on the silicon carbide crystal.

In an embodiment of the disclosure, the above atomic layer deposition unit uses a crystal growing furnace as a chamber.

In an embodiment of the disclosure, the above atomic layer deposition unit does not have another chamber.

In an embodiment of the disclosure, the above silicon carbide crystal growing apparatus further includes a gas channel configured to connect the internal space and the atomic layer deposition unit.

In an embodiment of the disclosure, the above physical vapor transport unit includes a pump configured to perform a negative pressurizing operation on the internal space.

In an embodiment of the disclosure, the above silicon carbide crystal growing apparatus further includes a butterfly valve configured to control the pressure in the internal space.

In an embodiment of the disclosure, the silicon carbide crystal is a semi-insulating silicon carbide crystal or an N-type silicon carbide crystal.

In an embodiment of the disclosure, the silicon carbide crystal growing apparatus further includes a controller configured to control the process parameters of the atomic layer deposition unit.

In an embodiment of the disclosure, the process parameters include switching speed, length of turn-on time, switching frequency, number of switching or a combination thereof.

The silicon carbide crystal growing method in the disclosure includes the following steps: (a) growing silicon carbide crystals in an internal space of the crystal growing furnace of the physical vapor transport unit; (b) performing atomic doping on the silicon carbide crystal in the growing state with the precursor of the atomic layer deposition unit while simultaneously performing step (a).

In an embodiment of the disclosure, the silicon carbide crystal growing method further includes providing a pre-precursor and controlling the temperature range of the pre-precursor to be between 0° C. and 250° C. to form the precursor in a gaseous state.

In an embodiment of the disclosure, the pre-precursor is a solid-state compound, a liquid-state compound or a combination thereof.

In an embodiment of the disclosure, the pre-precursor includes organic materials, inorganic materials, or a combination thereof.

In an embodiment of the disclosure, the pre-precursor includes vanadium-based, boron-based, aluminum-based compounds, or a combination thereof.

In an embodiment of the disclosure, the pre-precursor is tetrakis (dimethylamino) vanadium, boron tribromide, trimethylalane, or a combination thereof.

In an embodiment of the disclosure, the silicon carbide crystal growing method further includes a vacuum gauge configured to measure the saturation vapor pressure of the precursor and confirm the pipeline pressure in the atomic layer deposition unit.

In an embodiment of the disclosure, the saturation vapor pressure of the precursor ranges from 0.01 torr to 100 torr.

In an embodiment of the disclosure, the silicon carbide crystal growing method further includes mixing the process gas required by the physical vapor transport unit into the precursor so as to be introduced into the internal space.

In an embodiment of the disclosure, the process gas includes argon, hydrogen, nitrogen, ammonia, oxygen, or a combination thereof.

In an embodiment of the disclosure, the temperature range of the precursor is between 0° C. and 250° C.

Based on the above, in the disclosure, with the combination of the physical vapor transport unit and the atomic layer deposition unit, the doping effect can be improved by using the atomic layer deposition unit to perform atomic doping operation on the silicon carbide crystal in the physical vapor transport unit, thereby reducing the probability of adversely affecting the resistivity and crystal yield of the silicon carbide crystal due to excessive or uneven doping, and reducing the impurities in the crystal to improve the purity of the crystal, thus enhancing the reliability and quality of subsequent products.

In order to make the above features and advantages of the disclosure more comprehensible, embodiments are described below in detail with the accompanying drawings as follows.

### BRIEF DESCRIPTION OF THE DRAWINGS

FIG. 1 is a schematic view of a silicon carbide crystal growing apparatus according to some embodiments of the disclosure.

FIG. 2 is a schematic view of a silicon carbide crystal growing apparatus according to one of the embodiments in FIG. 1.

FIG. 3 is a flowchart of a silicon carbide crystal growing method according to an embodiment of the disclosure.

### DESCRIPTION OF EMBODIMENTS

The exemplary embodiments of the disclosure will be fully described below with reference to the drawings, but the disclosure may also be implemented in many different forms and should not be construed as being limited to the embodiments described herein. In the drawings, for clarity, the size and thickness of each area, part, and layer may not be drawn according to actual scale. For ease of understanding, the same elements in the following description will be described with the same symbols.

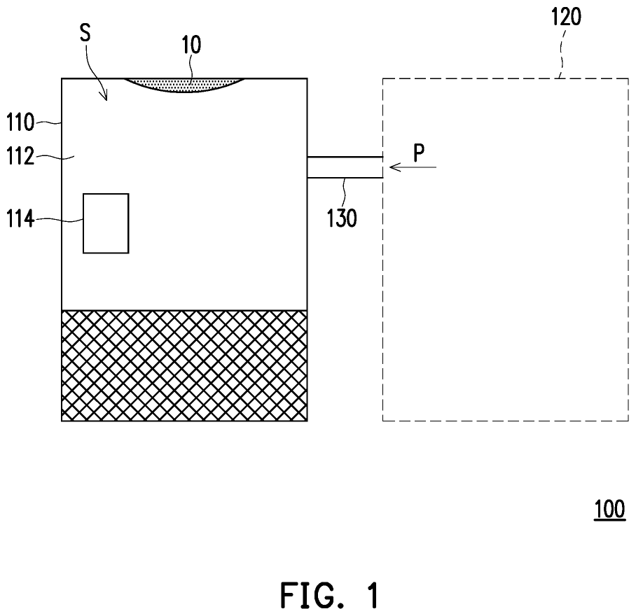

FIG. 1 is a schematic view of a silicon carbide crystal growing apparatus according to some embodiments of the disclosure. Referring to FIG. 1, the silicon carbide crystal growing apparatus 100 includes a physical vapor transport (PVT) unit 110 and an atomic layer deposition (ALD) unit 120. The physical vapor transport unit 110 has a crystal growing furnace 112 configured to grow silicon carbide crystals 10 in the internal space S of the crystal growing furnace 112. The atomic layer deposition unit 120 is coupled to the crystal growing furnace 112 and configured to perform an atomic doping operation on the silicon carbide crystal 10. Here, the physical vapor transport unit 110 grows the silicon carbide crystal 10 in the internal space S of the crystal growing furnace 112 by a sublimation method, for example. The sublimation method, for example, sublimates silicon carbide powder (not shown) through high temperature, and then condenses the sublimated silicon carbide powder into nucleus to grow into the silicon carbide crystal 10. In addition, the atomic doping may be doping of the dopant in the form of atoms.

Therefore, with the combination of the physical vapor transport unit 110 and the atomic layer deposition unit 120, the silicon carbide crystal growing apparatus 100 can perform atomic doping operation on the silicon carbide crystal 10 in the physical vapor transport unit 110 by using the atomic layer deposition unit 120, thus improving the doping effect, thereby reducing the probability of adversely affecting the resistivity and crystal yield of the silicon carbide crystal 10 while reducing the impurities in the crystal to improve the purity of the crystal, such that the reliability and quality of subsequent products can be enhanced. Further, the atomic doping property of the atomic layer deposition unit 120 can more accurately control the doping amount of the dopant, so as to reduce the probability of adversely affecting the resistivity of the silicon carbide crystal 10 due to excessive doping, and such property allows a more uniform doping distribution to be formed in the silicon carbide crystal 10 to reduce the probability of adversely affecting the crystal yield of the silicon carbide crystal 10 due to the uneven doping distribution.

In an embodiment, the atomic layer deposition unit 120 may use the crystal growing furnace 112 as a chamber to directly perform atomic doping operation in the internal space S of the crystal growing furnace 112. Therefore, with the combination of the physical vapor transport unit 110 and the atomic layer deposition unit 120, the atomic layer deposition unit 120 may not have another chamber, so the illustration is shown by dashed line in FIG. 1, and therefore has the advantage of reducing the accommodation space required by the silicon carbide crystal growing apparatus 100, but the disclosure is not limited thereto. In other embodiments that are not shown, the atomic layer deposition unit may have another chamber for accommodating related components in the unit.

In an embodiment, the silicon carbide crystal growing apparatus 100 may further include a gas channel 130 configured to connect the internal space S and the atomic layer deposition unit 120. Further, the gas channel 130 is configured to transport the material of the atomic layer deposition unit 120 into the internal space S to perform atomic doping operation on the silicon carbide crystal 10. In addition, the physical vapor transport unit 110 may include a pump 114 configured to perform a negative pressurizing operation (create vacuum) on the internal space S. Therefore, the material of the atomic layer deposition unit 120 may be introduced into the internal space S through the gas channel 130 with a pressure difference so as to perform the atomic doping operation on the silicon carbide crystal 10. In an embodiment, the crystal growing furnace 112 may be equipped with a butterfly control isolation valve (not shown) to control the pressure in the internal space S, so that the material of the atomic layer deposition unit 120 can be smoothly introduced into the internal space S through the gas channel 130 with the pressure difference. However, the disclosure is not limited thereto. The material of the atomic layer deposition unit 120 may enter the internal space S through other suitable methods to perform the atomic doping operation on the silicon carbide crystal 10.

In an embodiment, the silicon carbide crystal 10 grown in the silicon carbide crystal growing apparatus 100 may be a semi-insulating silicon carbide crystal or an N-type silicon carbide crystal. The semi-insulating silicon carbide crystal is defined as, for example, having the resistivity of 10⁴ Ω·cm to 10⁸ Ω·cm, and the N-type silicon carbide crystal is defined as, for example, having the resistivity of 10⁻³ Ω·cm to 10⁴ Ω·cm. However, the disclosure is not limited thereto, and the silicon carbide crystal growing apparatus 100 can be used to grow any suitable silicon carbide crystals.

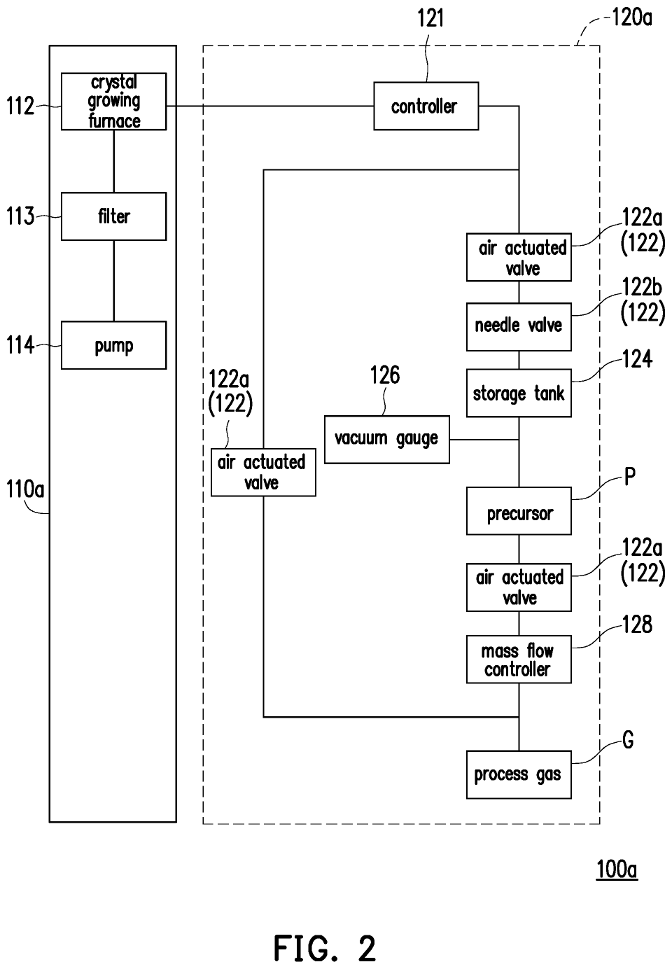

FIG. 2 is a schematic view of a silicon carbide crystal growing apparatus according to one of the embodiments in FIG. 1. It should be noted that the example of the silicon carbide crystal growing apparatus 100 in FIG. 1 may be the silicon carbide crystal growing apparatus 100a in FIG. 2, so the same or similar reference numerals are used in FIG. 1 and FIG. 2 to indicate the same or similar elements, and the description of the same technical content is omitted. For the description of the omitted parts, reference may be made to the foregoing embodiments and will not be repeated in the following embodiments.

Please refer to FIG. 2. The physical vapor transport unit 110a of the silicon carbide crystal growing apparatus 100a of this embodiment may include a crystal growing furnace 112, a filter 113 and a pump 114. In addition, the atomic layer deposition unit 120a may include a controller 121, a plurality of valves 122, a storage tank 124, a vacuum gauge 126, and a mass flow controller 128. Further, the controller 121 can be used to control the process parameters of the atomic layer deposition unit 120a to quickly and effectively control the doping of the atomic layer deposition unit 120a. For example, the controller 121 can control the process parameters such as the switching speed (measured in milliseconds), the length of the turn-on time, the switching frequency, and the number of switching of the atomic layer deposition unit 120a, but the disclosure is not limited thereto. The process parameters controlled by the controller 121 may depend on the actual design requirements. In addition, the vacuum gauge 126 may be used to confirm the pipeline pressure of the atomic layer deposition unit 120a and measure the saturation vapor pressure of the precursor P. On the other hand, the plurality of valves 122 including a plurality of air actuated valves 122a and the needle valve 122b as well as the mass flow controller 128 can be used to control the flow states of the precursor P and the process gas G.

It should be noted that the disclosure is characterized by the combination of the physical vapor transport unit 110 and the atomic layer deposition unit 120. Therefore, the disclosure provides no limitation to the components and configuration of the physical vapor transport unit and the atomic layer deposition unit. For example, apart from the components and configurations described in the foregoing embodiments, the physical vapor transport unit and the atomic layer deposition unit of the disclosure may be adjusted and designed with the physical vapor transport system and atomic layer deposition system commonly known to those of ordinary skill in the art, all of which fall within the scope of the disclosure as long as the physical vapor transport unit can be used to grow silicon carbide crystals and the atomic layer deposition unit can be used to perform atomic doping operation on the silicon carbide crystals.

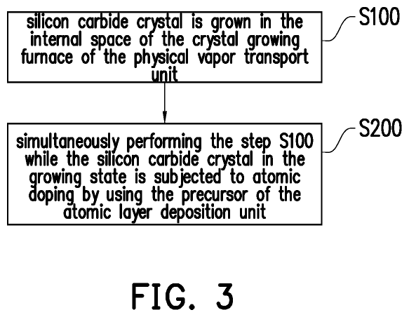

The main flow of the silicon carbide growing method according to an embodiment of the disclosure will be described below through drawings. FIG. 3 is a flowchart of a silicon carbide crystal growing method according to an embodiment of the disclosure. Please refer to FIG. 1 to FIG. 3. First, the silicon carbide crystal 10 is grown in the internal space S of the crystal growing furnace 112 of the physical vapor transport unit 110 (step S100). Next, while performing the step S100, the silicon carbide crystal 10 in the growing state is subjected to atomic doping by using the precursor P of the atomic layer deposition unit 120 (step S200).

Therefore, compared to adding dopant of powder particle size to SiC powder to grow the desired silicon carbide crystal, in the disclosure with the combination of the physical vapor transport unit 110 and the atomic layer deposition unit 120, the doping effect can be improved by using the precursor P of the atomic layer deposition unit 120 to perform atomic doping on the silicon carbide crystal 10 in the growing state, thus reducing the probability of adversely affecting the resistivity and crystal yield of the silicon carbide crystal 10 due to excessive or uneven doping, such that the reliability and quality of subsequent products can be enhanced.

In an embodiment, the gaseous precursor P can be formed and then doped into silicon carbide crystal 10 by providing a pre-precursor and controlling the temperature range of the pre-precursor, for example, between 0° C. and 250° C. (not shown). The saturation vapor pressure range of the precursor P is, for example, between 0.01 torr and 100 torr. In some embodiments, the pre-precursor may include a solid-state compound, a liquid-state compound, or a combination thereof. In some embodiments, the pre-precursor may include organic materials, inorganic materials, or a combination thereof. In some embodiments, the pre-precursor may include a high activity material, a low activity material, or a combination thereof. In some embodiments, the pre-precursor may include a vanadium-based, boron-based, aluminum-based compound, or a combination thereof. For example, the pre-precursor is tetrakis (dimethylamino) vanadium, boron tribromide, trimethylalane, or a combination thereof. However, the disclosure is not limited thereto, and the saturation vapor pressure and type of the precursor P and the type of the pre-precursor can be selected according to actual design requirements.

In an embodiment, the steps of the silicon carbide crystal growing method may further include mixing the process gas G required by the physical vapor transport unit 110 into the precursor P so as to be introduced into the internal space S, therefore, the process gas G may not be additionally introduced into the internal space S through another pipeline, thereby simplifying the manufacturing process. The process gas G may include argon, hydrogen, nitrogen, ammonia, oxygen, or a combination thereof. Further, the process gas G can be introduced into corresponding and suitable gas so as to be delivered to the internal space S based on the requirement in actual application. For example, when the process gas G is nitrogen, the formed silicon carbide crystal 10 can be applied to the manufacture of power devices, but the disclosure is not limited thereto. In addition, in an embodiment, the process gas G may be introduced into the internal space S along with the precursor P in a temperature range of 0° C. to 250° C. by negative pressure, but the disclosure is not limited thereto.

In summary, in the disclosure, with the combination of the physical vapor transport unit and the atomic layer deposition unit, the doping effect can be improved by using the atomic layer deposition unit to perform atomic doping operation on the silicon carbide crystal in the physical vapor transport unit, thereby reducing the probability of adversely affecting the resistivity and crystal yield of the silicon carbide crystal due to excessive or uneven doping, and reducing the impurities in the crystal to improve the purity of the crystal, thus enhancing the reliability and quality of products. Furthermore, the atomic layer deposition unit may use the crystal growing furnace as a chamber to directly perform atomic doping operation in the internal space of the crystal growing furnace. Therefore, with the combination of the physical vapor transport unit and the atomic layer deposition unit, the disclosure further has the advantage of reducing the accommodation space required by the silicon carbide crystal growing apparatus. Moreover, the steps of the silicon carbide crystal growing method may further include mixing the process gas required by the physical vapor transport unit into the precursor so as to be introduced into the internal space, therefore, the process gas may not be additionally introduced into the internal space through another pipeline, thereby simplifying the manufacturing process.

Although the present disclosure has been disclosed in the above embodiments, it is not intended to limit the present disclosure, and those of ordinary skills in the art can make some modifications and refinements without departing from the spirit and scope of the disclosure. Therefore, the scope of the present disclosure is subject to the definition of the scope of the appended claims.

What is claimed is:

1. A silicon carbide crystal growing apparatus, comprising:
a physical vapor transport unit having a crystal growing furnace configured to grow a silicon carbide crystal in an internal space of the crystal growing furnace;
an atomic layer deposition unit, coupled to the crystal growing furnace, and configured to perform an atomic doping operation on the silicon carbide crystal.

2. The silicon carbide crystal growing apparatus according to claim 1, wherein the atomic layer deposition unit uses the crystal growing furnace as a chamber.

3. The silicon carbide crystal growing apparatus according to claim 2, wherein the atomic layer deposition unit does not have another chamber.

4. The silicon carbide crystal growing apparatus according to claim 1, further comprising a gas channel configured to connect the internal space and the atomic layer deposition unit.

5. The silicon carbide crystal growing apparatus according to claim 4, wherein the physical vapor transport unit comprises a pump configured to perform a negative pressurizing operation in the internal space.

6. The silicon carbide crystal growing apparatus according to claim 5, further comprising a butterfly valve configured to control the pressure in the internal space.

7. The silicon carbide crystal growing apparatus according to claim 1, wherein the silicon carbide crystal is a semi-insulating silicon carbide crystal or an N-type silicon carbide crystal.

8. The silicon carbide crystal growing apparatus according to claim 1, further comprising a controller configured to control process parameters of the atomic layer deposition unit.

9. The silicon carbide crystal growing apparatus according to claim 8, wherein the process parameters comprise switching speed, length of turn-on time, switching frequency, number of switching or a combination thereof.

10. A silicon carbide crystal growing method, comprising:
(a) growing a silicon carbide crystal in an internal space of a crystal growing furnace of a physical vapor transport unit; and
(b) performing atomic doping on the silicon carbide crystal in a growing state with a precursor of an atomic layer deposition unit while simultaneously performing step (a).

11. The silicon carbide crystal growing method according to claim 10, further comprising:
providing a pre-precursor and controlling a temperature range of the pre-precursor to be between 0° C. and 250° C. to form the precursor in a gaseous state.

12. The silicon carbide crystal growing method according to claim 11, wherein the pre-precursor is a solid-state compound, a liquid-state compound or a combination thereof.

13. The silicon carbide crystal growing method according to claim 11, wherein the pre-precursor comprises organic materials, inorganic materials, or a combination thereof.

14. The silicon carbide crystal growing method according to claim 11, wherein the pre-precursor comprises vanadium-based, boron-based, aluminum-based compounds, or a combination thereof.

15. The silicon carbide crystal growing method according to claim 11, wherein the pre-precursor is tetrakis (dimethylamino) vanadium, boron tribromide, trimethylalane, or a combination thereof.

16. The silicon carbide crystal growing method according to claim 10, further comprising a vacuum gauge configured to measure a saturation vapor pressure of the precursor and confirm a pipeline pressure in the atomic layer deposition unit.

17. The silicon carbide crystal growing method according to claim 16, wherein the saturation vapor pressure of the precursor ranges from 0.01 torr to 100 torr.

18. The silicon carbide crystal growing method according to claim 10, further comprising mixing a process gas required by the physical vapor transport unit into the precursor so as to be introduced into the internal space.

19. The silicon carbide crystal growing method according to claim 18, wherein the process gas comprises argon, hydrogen, nitrogen, ammonia, oxygen, or a combination thereof.

20. The silicon carbide crystal growing method according to claim 18, wherein a temperature range of the precursor is between 0° C. and 250° C.
